(19) United States
(12) Patent Application Publication
(10) Pub. No.: US 2015/0372695 A1
(43) Pub. Date: Dec. 24, 2015

(54) METHOD AND APPARATUS OF LDPC DECODER WITH LOWER ERROR FLOOR

(71) Applicants: Jian LI, (US); Changlong XU, (US); Yisheng XUE, (US); Jilei HOU, (US); Yin HUANG, (US); QUALCOMM INCORPORATED, San Diego, CA (US)

(72) Inventors: Jian Li, Beijing (CN); Changlong Xu, Beijing (CN); Yisheng Xue, San Diego, CA (US); Jilei Hou, San Diego, CA (US); Yin Huang, Beijing (CN)

(21) Appl. No.: 14/766,740

(22) PCT Filed: Mar. 14, 2013
(86) PCT No.: PCT/CN2013/072611

§ 371 Date: Aug. 7, 2015

(51) Int. Cl. H03M 13/11; H04L 1/00

(52) U.S. Cl. CPC H03M 13/1131; H04L 1/0045

(57) ABSTRACT

A method of error correction using low density parity check (LDPC) codes is disclosed. A communications device receives a codeword and detects one or more bit errors in the received codeword using an LDPC code. The device then generates a corrected codeword based, at least in part, on a set of unsatisfied check nodes of the LDPC code. The device may determine that the one or more bit errors are associated with an absorption set of the LDPC code. The device may also determine a plurality of candidate codewords based on the set of unsatisfied check node and select the corrected codeword from the plurality of candidate codewords. Each of the plurality of candidate codewords may represent a valid codeword associated with the LDPC code.

### TECHNICAL FIELD

The present embodiments relate generally to error detection in data communications, and specifically to error detection and/or correction based on low density parity check (LDPC) encoding.

### BACKGROUND OF RELATED ART

Many communications systems use error-correcting codes. Specifically, error correcting codes may compensate for the intrinsic unreliability of information transfer in these systems by introducing redundancy into the data stream. Low density parity check (LDPC) codes are a particular type of error correcting codes which use an iterative coding system. LDPC codes can be represented by bipartite graphs (often referred to as “Tanner graphs”), wherein a set of variable nodes corresponds to the information bits of a codeword, and a set of check nodes represents the parity-check constraints that define the code. A variable node and a check node are considered “neighbors” if they are connected by an edge in the graph. A bit sequence having a one-to-one association with the variable node sequence is a valid codeword if and only if, for each check node, the bits associated with all neighboring variable nodes sum to zero modulo two (i.e., they include an even number of 1's).

For example, FIG. 1A shows a bipartite graph 100 representing an exemplary LDPC code. The bipartite graph 100 includes a set of 5 variable nodes 110 (represented by circles) connected to 4 check nodes 120 (represented by squares). Edges in the graph 100 connect the variable nodes 110 to the check nodes 120. FIG. 1B shows a matrix representation 150 of the bipartite graph 100. The matrix representation 150 includes a parity check matrix H and a codeword vector x, where x₁-x₅ represent bits of the codeword x. More specifically, the codeword vector x represents a valid codeword if and only if Hx=0.

A received LDPC codeword can be decoded to produce a reconstructed version of the original codeword. In the absence of errors, or in the case of correctable errors, decoding can be used to recover the original data unit that was encoded. For example, LDPC decoder may operate by exchanging messages within the bipartite graph 100, along the edges, and updating these messages by performing computations at the nodes based on the incoming messages. Each variable node 110 in the graph 100 may initially be provided with a “soft bit” (e.g., representing the received bit of the codeword) that indicates an estimate of the associated bit's value as determined by observations from the communications channel. The LDPC decoders may update the soft bits by iteratively reading them from, and writing them back to, memory based on the parity check constraints of the corresponding LDPC code.

The 802.3an Ethernet standard (e.g., 10GBASE-T) establishes an LDPC coding scheme based on generalized Reed-Solomon codes. For example, FIG. 2 shows a bipartite graph 200 representing an exemplary portion of an LDPC code that may be used in the 802.3an Ethernet standard. The bipartite graph 200 includes a set of 8 variable nodes 210 connected to 28 check nodes 220 and 230. The set of variable nodes 210 is referred to as an “absorption set” because the majority of each variable node's neighbors (e.g., the check nodes 220) are connected to the set 210 an even number of times, while a minority of the neighbors (e.g., the check nodes 230) are connected to the set 210 an odd number of times. Specifically, the set of check nodes 220 includes 20 second-degree check nodes (i.e., check nodes that are connected to the absorption set 210 twice), and the set of check nodes 230 includes 8 first-degree check nodes (i.e., check nodes that are connected to the absorption set 210 only once).

The absorption set 210 contributes to the error floor in 10GBASE-T Ethernet systems because decoding errors associated with the absorption set 210 cannot be properly decoded and/or corrected by standard LDPC decoding operations. For example, the soft bits within the absorption set 210 may satisfy all 20 parity checks associated with the set of second-degree check nodes 220, but fail to satisfy the remaining 8 parity checks associated with the set of first-degree check nodes 230. Accordingly, each variable node in the absorption set 210 receives one message from a first-degree check node 230 attempting to correct the error, while also receiving messages from five second-degree check nodes 220 reinforcing the error. As a result, such an error may be uncorrectable using standard LDPC decoding techniques and may therefore trigger retransmission of the entire codeword.

### SUMMARY

This Summary is provided to introduce in a simplified form a selection of concepts that are further described below in the Detailed Description. This Summary is not intended to identify key features or essential features of the claimed subject matter, nor is it intended to limit the scope of the claimed subject matter.

A device and method of operation are disclosed that may aid in the recovery of data received from another device. For some embodiments, the device may include a receiver to receive a codeword; a low density parity check (LDPC) decoder to perform an LDPC decoding operation on the received codeword using an LDPC code and to detect one or more bit errors in the received codeword; and a processor to generate a corrected codeword based, at least in part, on a set of unsatisfied check nodes from the LDPC decoding operation. The processor may also determine whether the one or more bit errors in the received codeword are associated with an absorption set of the LDPC code. The processor may also determine a plurality of candidate codewords based on the set of unsatisfied check nodes, wherein each of the plurality of candidate codewords represents a valid codeword associated with the LDPC code; and select the corrected codeword from the plurality of candidate codewords.

For some embodiments, the corrected codeword may be generated by determining a plurality of candidate codewords based on the set of unsatisfied check nodes, wherein each of the plurality of candidate codewords represents a valid codeword associated with the LDPC code; and selecting the corrected codeword from the plurality of candidate codewords.

For some embodiments, the plurality of candidate may be generated by identifying one or more absorption sets in the LDPC code that are associated with the set of unsatisfied check nodes; and for each of the one or more absorption sets, determining a set of codewords that satisfies a plurality of parity check constraints associated with that absorption set. The corrected codeword may be selected from the plurality of candidate codewords in response to a Euclidean distance between the received codeword and each of the plurality of candidate codewords.

By generating a corrected codeword to replace a received codeword with errors, the present embodiments may eliminate the need to retransmit the received codeword in the event of some LDPC decoding errors. This, in turn, may lower (and potentially eliminate) the error floor in 10GBASE-T Ethernet systems.

### BRIEF DESCRIPTION OF THE DRAWINGS

The present embodiments are illustrated by way of example and are not intended to be limited by the figures of the accompanying drawings, where:

FIGS. 1A-1B show graphical and matrix representations of an exemplary LDPC code;

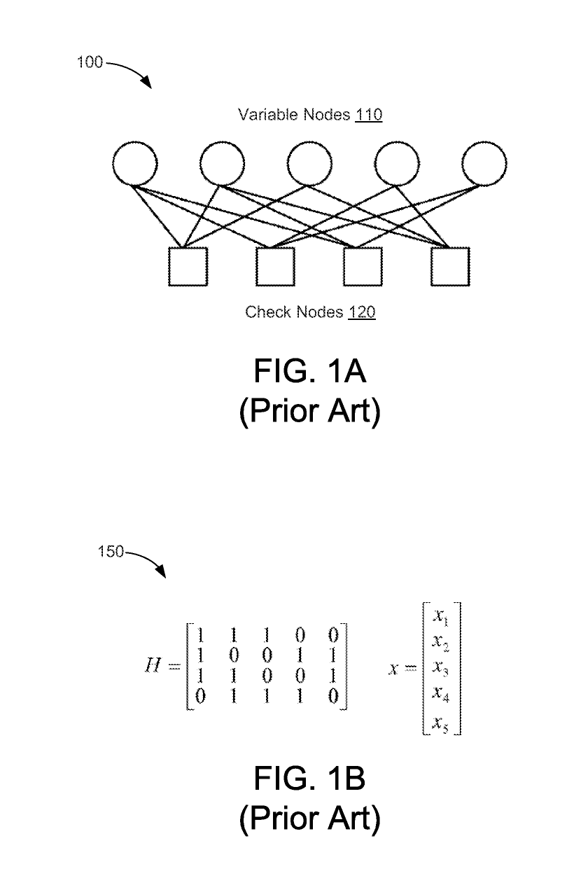

FIG. 2 shows a bipartite graph representing an exemplary portion of an LDPC code that may be used in the IEEE 802.3an Ethernet standard;

FIG. 3 shows a communications system in accordance with some embodiments;

FIG. 4 is an illustrative flow chart depicting an LDPC error correction operation in accordance with some embodiments;

FIG. 5 shows an embodiment of a decoder having post-LDPC decoding error correction capabilities;

FIG. 6 is a block diagram of an LDPC processing device in accordance with some embodiments;

FIG. 7 shows a more detailed embodiment of the decoder depicted in FIG. 6;

FIG. 8 is an illustrative flow chart depicting a decoding operation in accordance with some embodiments; and

FIG. 9 is an illustrative flow chart depicting a post-LDPC processing operation in accordance with some embodiments.

### DETAILED DESCRIPTION

In the following description, numerous specific details are set forth such as examples of specific components, circuits, and processes to provide a thorough understanding of the present disclosure. The term “coupled” as used herein means connected directly to or connected through one or more intervening components or circuits. Also, in the following description and for purposes of explanation, specific nomenclature is set forth to provide a thorough understanding of the present embodiments. However, it will be apparent to one skilled in the art that these specific details may not be required to practice the present embodiments. In other instances, well-known circuits and devices are shown in block diagram form to avoid obscuring the present disclosure. Any of the signals provided over various buses described herein may be time-multiplexed with other signals and provided over one or more common buses. Additionally, the interconnection between circuit elements or software blocks may be shown as buses or as single signal lines. Each of the buses may alternatively be a single signal line, and each of the single signal lines may alternatively be buses, and a single line or bus might represent any one or more of a myriad of physical or logical mechanisms for communication between components. The present embodiments are not to be construed as limited to specific examples described herein but rather to include within their scope all embodiments defined by the appended claims.

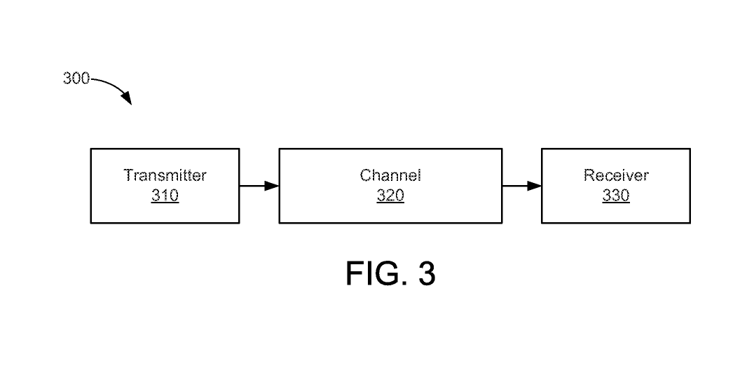

FIG. 3 shows a communications system 300 in accordance with some embodiments. A transmitter 310 transmits a signal onto a channel 320, and a receiver 330 receives the signal from the channel 320. The transmitter 310 and receiver 330 may be, for example, computers, switches, routers, hubs, gateways, and/or similar devices. For some embodiments, the communications system is a 10GBASE-T Ethernet system based on the 802.3an Ethernet standard (e.g., the channel 320 is a wired link), although other wired communication standards may be employed by system 300. In other embodiments, the channel 320 may be wireless.

Imperfections of various components in the communications system 300 may become sources of signal impairment, and thus cause signal degradation. For example, imperfections in the channel 320 may introduce channel distortion, which may include linear distortion, multi-path effects, and/or Additive White Gaussian Noise (AWGN). To combat potential signal degradation, the transmitter 310 and the receiver 330 may include LDPC encoders and decoders, respectively. Specifically, the transmitter 310 may perform LDPC encoding on outgoing data to produce a codeword that can be subsequently decoded by the receiver 330 (e.g., through an LDPC decoding operation) to recover the original data. For some embodiments, the receiver 330 may perform an LDPC post-processing operation, in the event of an LDPC decoding error, to generate a valid codeword that most closely matches the original received codeword.

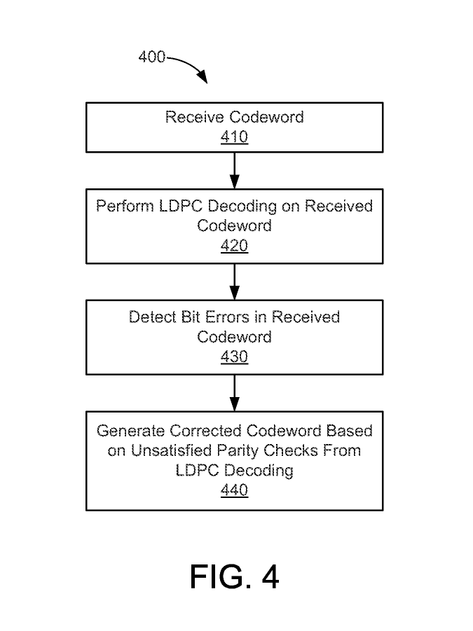

FIG. 4 is an illustrative flow chart depicting an LDPC error correction operation 400 in accordance with some embodiments. With reference, for example, to FIG. 3, the receiver 330 first receives a codeword from the transmitter 310 (410). For some embodiments, the codeword may be encoded based on an LDPC code that is shared between the transmitter 310 and the receiver 330. For example, the LDPC code may correspond to a (2048, 1723) regular LDPC code based on the 802.3an Ethernet standard (e.g., 10GBASE-T).

The receiver 330 performs LDPC decoding on the received codeword to check the validity of the received codeword bits (420). For example, the received codeword may include a set of information bits (e.g., the original data unit to be transmitted) and a set of parity bits (e.g., bits that are added to the original data unit during an encoding process to satisfy a set of parity-check constraints). The receiver 330 may apply the received codeword bits to a corresponding LDPC code (e.g., using a parity check matrix or bipartite graph (bigraph)) to determine whether the combination of information bits and parity bits represents a valid codeword for the LDPC code.

During the LDPC decoding process, the receiver 330 may detect one or more bit errors in the received codeword (430). As described above, imperfections in the channel 320 may cause interference or distortion in the transmission of codewords between the transmitter 310 and the receiver 330, thus resulting in one or more of the codeword bits being incorrectly received by the receiver 330. The receiver 330 may detect the one or more bit errors by determining whether any received codeword bits fail to satisfy a set of parity-check constraints when applied to a corresponding LDPC code.

For some embodiments, the receiver 330 may then generate a corrected codeword based, at least in part, on the set of unsatisfied parity checks from the LDPC decoding process (440). For example, the receiver 330 may generate (or identify) a set of candidate codewords that satisfy the parity checks that the received codeword failed to satisfy. For some embodiments, each candidate codeword in the set is a valid codeword for the corresponding LDPC code. In other words, each candidate codeword would satisfy all of the parity-check constraints in an LDPC decoding operation. The receiver 330 may then select the candidate codeword that most closely matches the received codeword as the corrected codeword. For some embodiments, the corrected codeword may correspond to the candidate codeword that is closest in Euclidean distance to the received codeword, as described in greater detail below.

It should be noted that, in some instances, one or more bit errors in the received codeword may be corrected via the LDPC decoding process (420). However, other bit errors may trigger a decoding error condition in the LDPC decoding process. For example, bit errors that are detected in an absorption set of the LDPC code may be uncorrectable through standard LDPC decoding because one set of parity checks may attempt to correct the error (e.g., the unsatisfied checks) while another set of parity checks may reinforce the error (e.g., the satisfied checks). In other words, the decoding error condition may stem from a disagreement between the parity checks over how the received codeword should be decoded, rather than a lack of information that would otherwise prevent the codeword from being properly decoded by any of the parity checks. Thus, for some embodiments, the receiver 330 may use the set of unsatisfied checks to produce a corrected codeword (440) only when (or alternatively, when) standard LDPC decoding (420) fails to properly decode a received codeword.

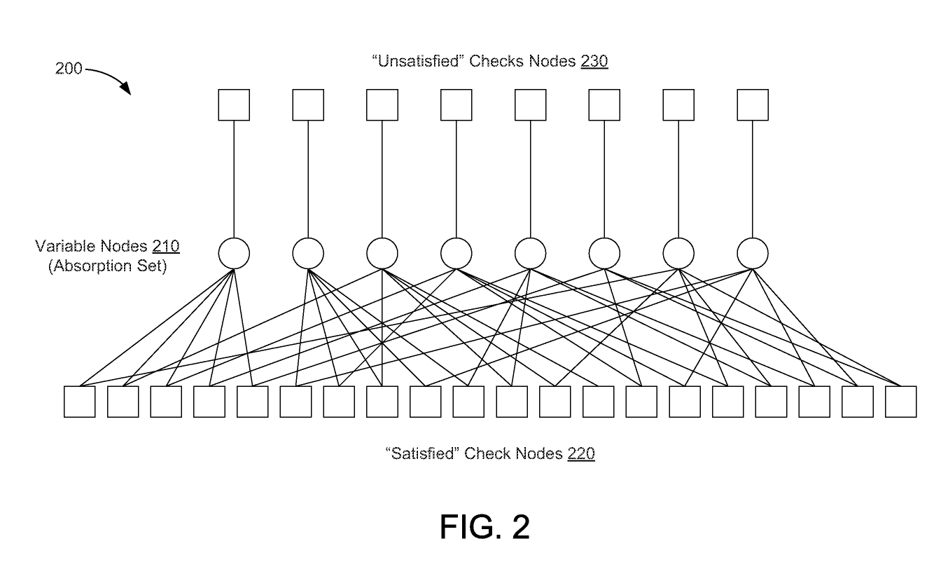

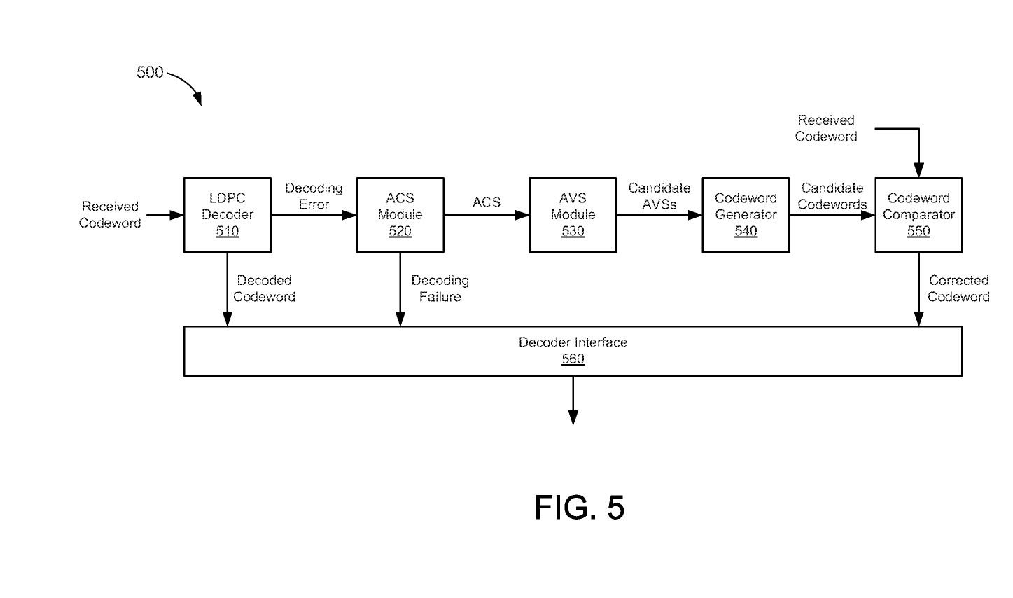

FIG. 5 shows an embodiment of an example decoder circuit 500 having post-LDPC decoding error correction capabilities. The decoder circuit 500 includes an LDPC decoder 510, an absorption check-node set (ACS) module 520, an absorption variable-node set (AVS) module 530, a codeword generator 540, a codeword comparator 550, and a decoder interface 560. It should be noted that the elements or modules 510-550 may be implemented in hardware or software, or any combination thereof. An AVS corresponds to a set of variable nodes that define an absorption set of an LDPC code. An ACS corresponds to a set of check nodes that are associated with an absorption set. For some embodiments, an ACS may correspond to a set of odd-degree check nodes (e.g., check nodes that are connected to the absorption set an odd number of times). For example, with reference to FIG. 2, the variable nodes 210 may represent an AVS for the LDPC code 200, and the unsatisfied first-degree check nodes 230 may represent an ACS for the LDPC code 200.

The LDPC decoder 510 receives an incoming codeword and outputs either a decoded codeword or a decoding error message. More specifically, the LDPC decoder 510 performs an LDPC decoding operation on the received codeword to check the validity of the bits in the received codeword. For example, if the received codeword bits satisfy a series of parity-check constraints associated with the LDPC code used in the decoding operation, and/or if any incorrect codeword bits can be correctly determined based on the parity-check constraints, then the LDPC decoder 510 may output the decoded codeword to the decoder interface 560. However, if the LDPC decoder 510 is unable to correct one or more bit errors in the received codeword (e.g., resulting in a decoding error condition), then the decoder 510 may output a decoding error message to the ACS module 520. For some embodiments, the decoding error message may indicate which parity check constraints produced the decoding error condition (e.g., the unsatisfied check nodes 230). For other embodiments, the decoding error message may indicate which bits of the received codeword the LDPC decoder 510 was unable to correct (e.g., the codeword bits associated with the variable nodes 210).

The ACS module 520 receives the decoding error message from the LDPC decoder 510 and outputs either a particular ACS or a decoding failure message. More specifically, the ACS module 520 determines, based on the decoding error message, whether bit errors in the received codeword fall within an absorption set of the LDPC code. For example, if the decoding error message specifies a set of check nodes that detected the error, the ACS module 520 may determine whether the set of check nodes corresponds to an ACS. If the decoding error message specifies which bits of the received codeword failed to decode properly, the ACS module 520 may determine whether those failed bits map to an AVS (and/or to an ACS). It should be noted that the absorption sets associated with an LDPC code can be predetermined. For example, the LDPC code used in the 802.3an Ethernet standard includes 14272 AVSs that map to 2328 ACSs. Thus, for some embodiments, a set of predetermined ACSs may be stored in an associated memory (not shown for simplicity). The ACS module 520 may then look up the failed check nodes or codeword bits (e.g., in a look-up table) to determine whether they correspond with an ACS of the LDPC code.

If the ACS module 520 determines that the decoding error condition was triggered by an absorption set of the LDPC code, then the ACS module 520 may output the ACS associated with the absorption set to the AVS module 530. For example, referring also to FIG. 2, if the LDPC decoder 510 detects 8 bit errors in a received LDPC codeword, then the ACS module 520 determines whether the 8 bit errors were detected in an absorption set of the LDPC code 200. If the 8 bit errors were detected in the 8 variable nodes 210 that form an absorption set, then the ACS module 520 outputs the set of unsatisfied check nodes 230 (e.g., the ACS associated with the absorption set 210). For some embodiments, the ACS module 520 may output a decoding failure message to the decoder interface 560 if the ACS module 520 determines that one or more bit errors do not fall within an absorption set of the LDPC code (e.g., the decoding error condition is not attributed to mere disagreement among the check nodes).

The AVS module 530 receives the ACS information from the ACS module 520 and outputs a set of candidate AVSs that are associated with the received ACS. In some embodiments, in order for a codeword to be valid, it should satisfy not only the ACS constraints but also any additional parity check constraints associated with the ACS. More specifically, multiple AVSs may map to the same ACS. For example, with reference to the IEEE 802.3an Ethernet standard, each of the 2328 ACSs is connected to 4, 8, 12, or 16 of the 14272 AVSs. Thus, a valid codeword should satisfy all parity check constraints (including the ACS) associated with at least one of the AVSs that are connected to the received ACS. For some embodiments, a set of candidate AVSs may be stored in memory for each ACS in the LDPC code. Thus, upon receiving ACS information from the ACS module 520, the AVS module 530 may look up each of the candidate AVSs for that ACS (e.g., in a look-up table).

The codeword generator 540 receives the candidate AVS information from the AVS module 530 and outputs a set of candidate codewords that satisfy the AVSs. More specifically, each of the candidate codewords may satisfy a set of parity checks associated with at least one of the AVSs in the received set. For some embodiments, the codeword generator 540 may generate the set of candidate codewords by determining, for each of n received AVSs, all valid codewords (x) (or alternatively a desired number of codewords) that satisfy the equation: Hₙx=0, where Hₙ is the parity-check matrix associated with the n^{th} AVS. For other embodiments, a set of predetermined candidate codewords may be stored in memory for each of the AVSs in the LDPC code. Thus, upon receiving a set of candidate AVSs from the AVS module 530, the codeword generator 540 may then look up a set of candidate codewords (e.g., in a lookup table) associated with each of the candidate AVSs.

The codeword comparator 550 receives the candidate codewords from the codeword generator 540 and outputs a corrected codeword to the decoder interface 560. More specifically, the codeword comparator 550 may compare each of the candidate codewords with the original received codeword to determine which of the candidate codewords most closely matches the received codeword. For example, by treating each codeword as a vector, the codeword comparator 550 may compare the “distances” between the received codeword and each of the candidate codewords to determine their respective degrees of similarity. The candidate codeword having the desired (e.g., minimum or alternatively, first one determined to be within a desired threshold) Euclidean distance to the received codeword will be the closest matching candidate. For some embodiments, the codeword comparator 550 may compare the received codeword vector (r) with each candidate codeword (c), for example, based on the following equation:

$$M = {\sum }_{i = 0}^{m} {r}_{i} {c}_{i}$$

where rᵢ represents the bits of the received codeword, cᵢ represents the bits of the candidate codeword, m is the codeword length (e.g., total number of bits in each codeword), and M is a similarity metric for the vectors r and c. Based on the equation above, the candidate codeword vector c having the shortest Euclidean distance to the received codeword vector r will produce the highest similarity metric M. Accordingly, the candidate codeword associated with the highest similarity metric M is most similar to the received codeword. The codeword comparator 550 may thus, in some embodiments, output the candidate codeword having the highest similarity metric M as the corrected codeword. In other embodiments, the codeword comparator 550 may output other codewords, e.g., a first compared codeword to have a “close enough” similarity metric M such that no further codewords are compared.

Note that where an LDPC decoding error occurs as a result of bit errors associated with an absorption set, only the set of bits associated with the absorption set are likely to differ between the candidate codewords and the received codeword. For example, if the LDPC decoder 510 discovers 8 bit errors in the received codeword, and the ACS module 520 determines that the bit errors are constrained to an 8-bit AVS, then each of the candidate AVSs output by the AVS module 530 may be an 8-bit AVS that maps to a corresponding 8-bit segment of a codeword. Accordingly, only the corresponding 8 bits may differ among any of the candidate codewords produced by the codeword generator 540. Thus, for some embodiments, the codeword comparator 550 may compare only a segment of the received and candidate codewords, for example, based the following equation:

$${M}^{′} = \vert {\sum }_{i = 0}^{7} {r}_{{s}_{i}} {c}_{{s}_{i}}$$

where rₛᵢ represents the bits of the received codeword at a variable node index s (which may vary depending on the candidate AVSs), cₛᵢ represents the bits of the candidate codeword at the variable node index s, and M′ is a similarity metric for the vectors r and c. From the equation above, the candidate codeword associated with the highest similarity metric M′ is most similar to the received codeword. The codeword comparator 550 may thus output the candidate codeword having the highest similarity metric M′ as the corrected codeword.

The decoder interface 560 receives a decoded codeword from the LDPC decoder 510, a decoding failure message from the ACS module 520, or a corrected codeword from the codeword comparator 550, and outputs the received information or data for further processing. For example, the decoder interface 560 may output the corrected (or decoded) codeword to be processed by a CPU (e.g., coupled to decoder circuit 500). Alternatively, the decoder interface 560 may output a decoding failure message to the CPU, thereby instructing the CPU to request retransmission of the previously received codeword.

By generating a corrected codeword to replace a received codeword with errors, the decoder circuit 500 may eliminate the need to retransmit the received codeword in the event of some LDPC decoding errors. This, in turn, lowers (and may potentially eliminate) the error floor in 10GBASE-T Ethernet systems.

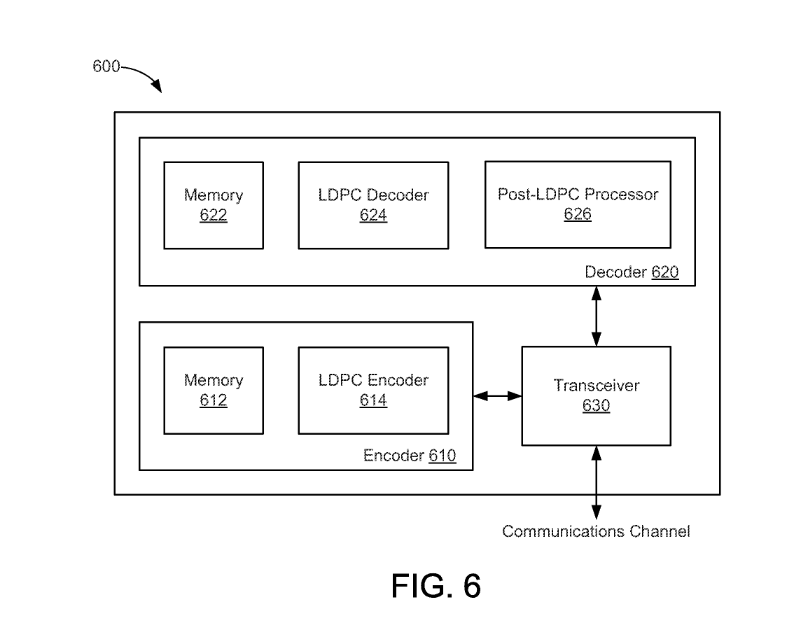

FIG. 6 is a block diagram of an LDPC processing device 600 in accordance with some embodiments. The LDPC processing device 600 includes an encoder 610, a decoder 620, and a transceiver 630 which transmits and/or receives LDPC-encoded codewords via a communications channel. For some embodiments, the communications channel may correspond to a 10GBASE-T Ethernet channel (although other communication mediums may be used). The encoder 610 includes a memory 612 and an LDPC encoder 614. Specifically, the memory 612 may store data to be encoded by the LDPC encoder 614. The LDPC encoder 614 processes the data stored in the memory 612 by generating codewords, based on an LDPC code, to be transmitted to another device. For some embodiments, the LDPC code may be a regular (2048, 1723) LDPC code based on the 802.3an Ethernet standard (e.g., 10GBASE-T). Accordingly, the LDPC encoder 614 may produce 2048-bit codewords.

The decoder 620 includes a memory 622, an LDPC decoder 624, and a post-LDPC processor 626. Specifically, the memory 622 may store codewords, received via the transceiver 630, to be decoded by the LDPC decoder 624. The LDPC decoder 624 processes the codewords stored in the memory 622 by performing parity check operations based on an LDPC code (note that the LDPC code used for decoding should correspond to the same LDPC code used for encoding). More specifically, the LDPC decoder 624 may verify the validity of the bits in the received codewords and/or attempt to correct, through the parity check operations, any bits that may have been received in error. For example, each parity check operation may involve reading a corresponding soft bit value from memory 622, combining the soft bit value with other soft bit values associated with a particular check node (e.g., a parity check constraint), and writing a bit value back to memory 622 that results from the check node operation. For some embodiments, the LDPC decoder 624 may include a plurality of processing elements to perform the parity check operations in parallel. If the LDPC decoder 624 is unable to correct one or more bit errors in a received codeword (thus resulting in a decoding error), then the decoder 624 may produce a decoding error message.

The post-LDPC processor 626 may generate a corrected codeword in the event of a decoding error in the LDPC decoder 624. For some embodiments, the post-LDPC processor 626 may determine, based on the information in the decoding error message, whether a corrected codeword may be generated through one or more post-processing operations. For example, the post-LDPC processor 626 may determine whether the bit errors of the received codeword fall within an absorption set of the LDPC code. If the bit errors are not associated with an absorption set of the LDPC code, the post-LDPC processor 626 may produce a decoding failure message. Otherwise, the post-LDPC processor 626 may generate a corrected codeword based, at least in part, on a set of unsatisfied check nodes from the LDPC decoding operation (e.g., performed by the LDPC decoder 624). For some embodiments, the post-LDPC processor 626 may generate the corrected codeword by first generating a plurality of candidate codewords (wherein each candidate codeword represents a valid codeword for the LDPC code), and selecting a candidate codeword that most closely matches the received codeword.

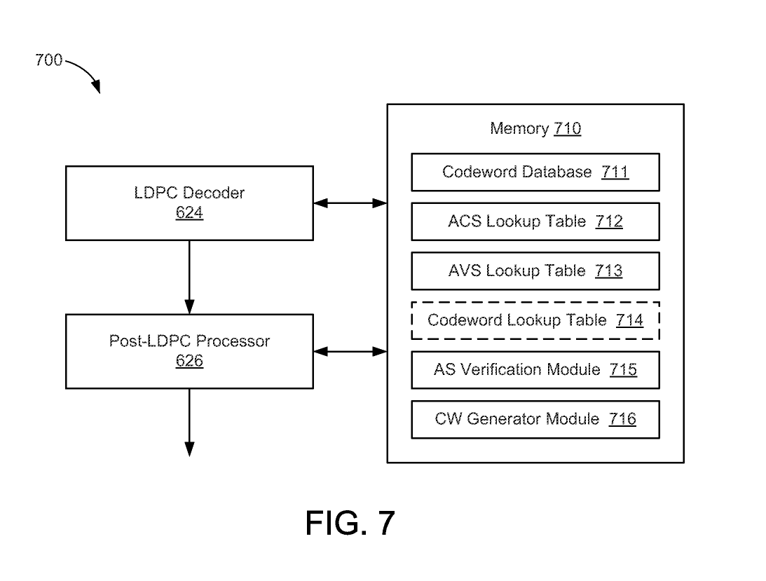

FIG. 7 shows a more detailed embodiment of the decoder 620 depicted in FIG. 6. The decoder 700 includes LDPC decoder 624, post-LDPC processor 626, and a memory 710. As described above, the LDPC decoder 624 may verify the validity of the bits in received codewords and/or attempt to correct (through LDPC decoding) any bits that may have been received in error. Codewords that are successfully verified or corrected by the LDPC decoder 624 are provided to the post-LDPC processor 626. If the LDPC decoder 624 is unable to correct one or more bit errors in a received codeword (thus resulting in a decoding error), the LDPC decoder 624 may output a decoding error message to the post-LDPC processor 626. For some embodiments, the decoding error message may indicate which parity check constraints (e.g., check nodes) produced the decoding error condition. For other embodiments, the decoding error message may indicate which bits of the received codeword the LDPC decoder 624 was unable to correct.

Memory 710 may include a codeword database 711 that can be used as a local cache to store received codewords, an ACS lookup table 712 that may be used to store a set of ACSs associated with an LDPC code, and an AVS lookup table 713 that may be used to store a set of AVSs associated with the LDPC code. For some embodiments, the ACS lookup table 712 may be cross-referenced with the AVS lookup table 713 such that an ACS stored in the ACS lookup table 712 may point to one or more AVSs stored in the AVS lookup table 713, and vice-versa. Further, for some embodiments, the memory 710 may include a codeword lookup table 714 that may be used to store one or more candidate codewords associated with each AVS in the AVS lookup table 713.

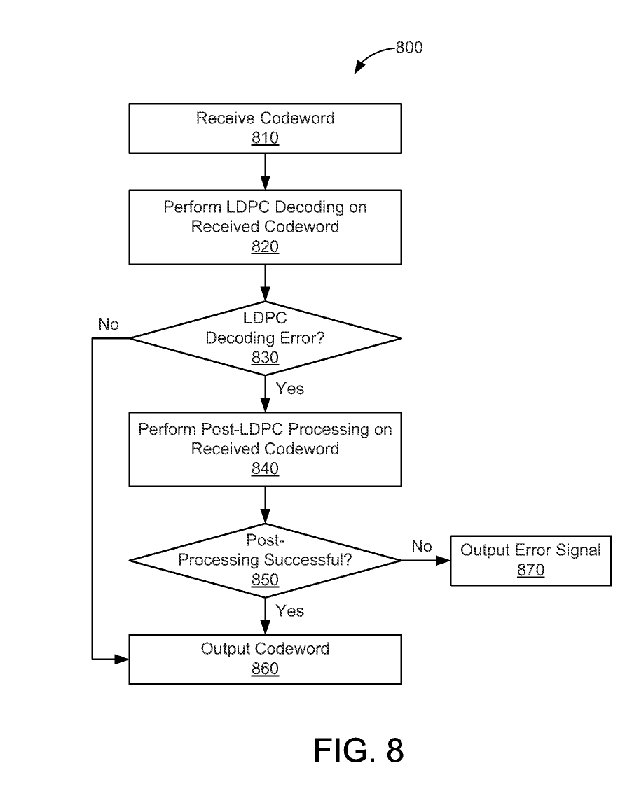

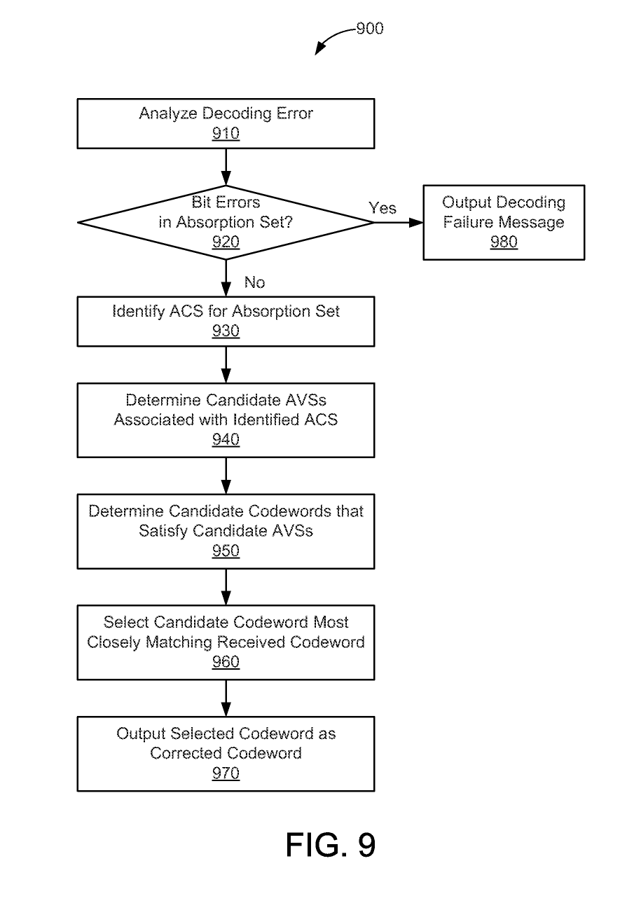

Furthermore, memory 710 may also include a non-transitory computer-readable storage medium (e.g., one or more nonvolatile memory elements, such as EPROM, EEPROM, Flash memory, a hard drive, etc.) that can store the following software modules:
an absorption set (AS) verification module 715 to determine whether an LDPC decoding error in the LDPC decoder 624 was a result of bit errors associated with an absorption set (or AVS) of the LDPC code; and
a codeword (CW) generator module 716 to generate a corrected codeword that most closely matches the received codeword based, at least in part, on a set of unsatisfied parity checks from the LDPC decoding operation.
   Each software module may include instructions that, when executed by the post-LDPC processor 626, may cause the decoder 700 to perform the corresponding function. Thus, the non-transitory computer-readable storage medium of memory 710 may include instructions for performing all or a portion of the operations described with respect to FIGS. 8-9.

The post-LDPC processor 626, which is coupled to the LDPC decoder 624 and memory 710, may be any suitable processor capable of executing scripts of instructions of one or more software programs stored in the decoder 700 (e.g., within memory 710). For example, the post-LDPC processor 626 can execute the AS verification module 715 and/or the CW generator module 716.

The AS verification module 715 may be executed by the post-LDPC processor 626 to determine whether an LDPC decoding error in the LDPC decoder 624 was a result of bit errors associated with an absorption set of the LDPC code, and thus correctable through post-processing. For example, the AS verification module 715, as executed by the post-LDPC processor 626, may determine, based on the decoding error message, whether the bit errors in the received codeword are associated with an absorption set of the LDPC code. For some embodiments, the post-LDPC processor 626 may look up the check nodes that produced the decoding error in the ACS lookup table 712 to determine whether they correspond to an ACS (and thus an absorption set) of the LDPC code. For other embodiments, the post-LDPC processor 626 may determine a set of variable nodes that the error bits map to, and the post-LDPC processor 626 may then look up the corresponding variable nodes in the AVS lookup table 713 to determine whether they correspond to an AVS of the LDPC code. If the post-LDPC processor 626, in executing the AS verification module 715, determines that the error bits in the received codeword do not map to an ACS and/or AVS, then the post-LDPC processor 626 may output a decoding failure message (e.g., to request retransmission of the previously received codeword). Otherwise, the post-LDPC processor 626, in executing the AS verification module 715, may identify the ACS associated with the bit errors in the received codeword.

The CW generator module 716 may be executed by the post-LDPC processor 626 to generate a corrected codeword that, e.g., most closely matches the received codeword based, at least in part, on the identified ACS. For example, the CW generator module 716, as executed by the post-LDPC processor 626, may determine a set of candidate AVSs that are associated with the identified ACS. For some embodiments, the post-LDPC processor 626 may look up the candidate AVSs in the AVS lookup table 713, using the ACS as a reference index.

The post-LDPC processor 626, in executing the CW generator module 716, may then determine a set of candidate codewords that satisfy the candidate AVSs. More specifically, each of the candidate codewords may satisfy a set of parity checks associated with at least one of the candidate AVSs. For some embodiments, the post-LDPC processor 626 may generate the set of candidate codewords by determining, for each of n received AVSs, all valid codewords (x) (or alternatively, a desired sufficient number of codewords) that satisfy the equation: Hₙx=0, where Hₙ is the parity-check matrix associated with the n^{th} AVS. For other embodiments, the post-LDPC processor 626 may simply look up the candidate codewords in the codeword lookup table 714 using the set of candidate AVSs as a reference index.

The CW generator module 716, as executed by the post-LDPC processor 626, may then compare each of the candidate codewords with the original received codeword to determine which of the candidate codewords, e.g., most closely matches the received codeword. The post-LDPC processor 626 may output the closest matching candidate codeword as the corrected codeword. For some embodiments, the post-LDPC processor 626 may compare the Euclidean distances between the received codeword and each of the candidate codewords to determine their respective degrees of similarity. For example, the candidate codeword having the shortest (e.g., minimum) distance to the received codeword may be selected as the corrected codeword.

FIG. 8 is an illustrative flow chart depicting a decoding operation 800 in accordance with some embodiments. As described above, the present embodiments may generate a corrected codeword (in the event of an LDPC decoding error) that most closely matches the original received codeword. Referring also to FIG. 6, in the operation 800, the LDPC processing device 600 first receives an LDPC-encoded codeword (810). For example, the transceiver 630 may receive the codeword (e.g., from another device) via a communications channel. The transceiver 630 may then forward the codeword to the decoder 620 for processing. For some embodiments, the received codeword may be stored in memory 622.

The LDPC processing device 600 performs LDPC decoding on the received codeword (820), and determines whether the received codeword bits are successfully decoded or a decoding error condition occurs (830). For example, the LDPC decoder 624 may perform a series of parity check operations on the received codeword, based on an LDPC code, through which the LDPC decoder 624 attempts to verify the validity of the bits in the received codewords and/or correct any bits that may have been received in error. For some embodiments, the LDPC decoder 624 may determine that a decoding error condition has occurred if the decoder 624 is unable to correct one or more bit errors in a received codeword using the parity check operations (i.e., via the LDPC decoding process).

If no decoding error condition is detected, as tested at 830, the LDPC processing device 600 may output the decoded codeword (860). For example, the LDPC processing device 600 may output the decoded codeword to a CPU for further processing. However, if a decoding error condition is detected at 830, then the LDPC processing device 600 may perform post-LDPC processing on the received codeword (840). For some embodiments, the post-LDPC processor 626 may attempt to generate a corrected codeword based, at least in part, on the bit errors in the received codeword. More specifically, the post-LDPC processor 626 may first determine whether a set of unsatisfied parity checks from the LDPC decoding operation (820) represent an absorption set of the LDPC code. If the unsatisfied parity checks do not correspond with an absorption set, the post-LDPC processor 626 may produce a decoding failure message. Otherwise, the post-LDPC processor 626 may generate a corrected codeword based on the set of unsatisfied parity checks.

The LDPC processing device 600 then determines whether the post-LDPC processing is successful (850). If unsuccessful, the LDPC processing device 600 outputs an error signal (e.g., to request retransmission of the previously received codeword) (870). However, if the post-LDPC processing is successful, then the LDPC processing device 600 outputs a corrected codeword in lieu of the received codeword (860). For example, the post-LDPC processing may be unsuccessful if the post-LDPC processor 626 returns a decoding failure message. Otherwise, the post-LDPC processor 626 returns a corrected codeword, thereby indicating a successful post-LDPC processing operation.

FIG. 9 is an illustrative flow chart depicting a post-LDPC processing operation 900 in accordance with some embodiments. Referring also to FIG. 7, in the operation 900, the decoder 700 first analyzes a decoding error produced while attempting to decode a received codeword using LDPC decoding (910). For example, the LDPC decoder 624 may output a decoding error message if the decoder 624 is unable to correct one or more bit errors in a received codeword.

The decoder 700 may then determine whether the bit errors in the received codeword are associated with an absorption set of the LDPC code (920). For example, the AS verification module 715, as executed by the post-LDPC processor 626, may determine, based on the decoding error message, whether the bit errors in the received codeword are associated with an absorption set of the LDPC code. If the bit errors do not correspond with an absorption set, as tested at 920, then the decoder may output a decoding failure message (980).

However, if the decoder 700 determines that the bit errors in the received codeword are associated with an absorption set of the LDPC code (920), then the decoder 700 may proceed to identify an ACS for the corresponding absorption set (930). For some embodiments, the post-LDPC processor 626, in executing the AS verification module 715, may identify the ACS from the ACS lookup table 712. For other embodiments, the post-LDPC processor 626 may identify the ACS by cross-referencing the AVS lookup table 713 with the ACS lookup table 712.

Next, the decoder 700 determines a set of candidate AVSs that are associated with the identified ACS (940). As described above, multiple AVSs may map to the same ACS for a particular LDPC code. Thus, a valid codeword (given a particular ACS) should satisfy all parity check constraints associated with at least one of the AVSs that are connected to the identified ACS. For some embodiments, the CW generator module 716, as executed by the post-LDPC processor 626, may look up the candidate AVSs in the AVS lookup table 713 using the identified ACS as a reference index.

The decoder 700 then determines a set of candidate codewords that satisfy the candidate AVSs (950). For some embodiments, the post-LDPC processor 626 may generate the set of candidate codewords by determining, for each of n received AVSs, all valid codewords (x) (or a desired sufficient number of codewords) that satisfy the equation: Hₙx=0, where Hₙ is the parity-check matrix associated with the n^{th} AVS. For other embodiments, the post-LDPC processor 626 may look up the candidate codewords in the codeword lookup table 714 using the set of candidate AVSs as a reference index.

Finally, the decoder 700 selects the candidate codeword that most closely matches the received codeword (960), and outputs the selected candidate codeword as the corrected codeword (970). For some embodiments, the post-LDPC processor 626 may compare the Euclidean distances between the received codeword and each of the candidate codewords to determine their respective degrees of similarity. For example, the candidate codeword having the shortest distance to the received codeword may be selected as the corrected codeword.

By generating a corrected codeword to replace a received codeword with errors, the post-LDPC processing operation 900 may eliminate the need to retransmit the received codeword in the event of some LDPC decoding errors. This, in turn, lowers (and may potentially eliminate) the error floor in 10GBASE-T Ethernet systems.

In the foregoing specification, the present embodiments have been described with reference to specific exemplary embodiments thereof. It will, however, be evident that various modifications and changes may be made thereto without departing from the broader scope of the disclosure as set forth in the appended claims. The specification and drawings are, accordingly, to be regarded in an illustrative sense rather than a restrictive sense. For example, the method steps depicted in the flow charts of FIGS. 4, 8, and 9 may be performed in other suitable orders, multiple steps may be combined into a single step, and/or some steps may be omitted.

What is claimed is:

1. A method of error correction in a communications system, comprising:
receiving a codeword;
performing a low density parity check (LDPC) decoding operation on the received codeword using an LDPC code, wherein the decoding operation comprises a plurality of check nodes to attempt to be satisfied by the codeword;
detecting one or more bit errors in the received codeword; and
generating a corrected codeword based, at least in part, on at least one unsatisfied check node of the plurality of check nodes.

2. The method of claim 1, further comprising:
determining whether the one or more bit errors are associated with an absorption set of the LDPC code.

3. The method of claim 2, wherein generating the corrected codeword comprises:
identifying the at least one unsatisfied check node based on the absorption set, wherein each of the at least one unsatisfied check node is a neighbor with an odd number of variable nodes in the absorption set.

4. The method of claim 1, wherein generating the corrected codeword comprises:
determining a plurality of candidate codewords based, at least in part, on the at least one unsatisfied check node, wherein each of the plurality of candidate codewords represents a valid codeword associated with the LDPC code; and
selecting the corrected codeword from the plurality of candidate codewords.

5. The method of claim 4, wherein determining the plurality of candidate codewords comprises:
identifying one or more absorption sets in the LDPC code that are associated with the at least one unsatisfied check node; and
for each of the one or more absorption sets, determining a set of codewords that satisfies a plurality of parity check constraints associated with the absorption set.

6. The method of claim 4, wherein determining the plurality of candidate codewords comprises:
looking up the plurality of candidate codewords in a lookup table.

7. The method of claim 4, wherein selecting the corrected codeword from the plurality of candidate codewords comprises:
selecting the corrected codeword based, at least in part, on a Euclidean distance between the received codeword and the corrected codeword.

8. The method of claim 7, wherein the corrected codeword corresponds to a candidate codeword of the plurality of candidate codewords having a shortest Euclidean distance to the received codeword.

9. The method of claim 1, wherein the one or more bit errors in the received codeword corresponds to a decoding error in the LDPC decoding operation.

10. The method of claim 1, wherein the communications system is a 10GBASE-T Ethernet system.

11. A computer-readable storage medium containing program instructions that, when executed by a processor provided within a communications device, causes the device to:
receive a codeword;
perform a low density parity check (LDPC) decoding operation on the received codeword using an LDPC code, wherein the decoding operation comprises a plurality of check nodes to attempt to be satisfied by the codeword;
detect one or more bit errors in the received codeword; and
generate a corrected codeword based, at least in part, on at least one unsatisfied check node of the plurality of check nodes.

12. The computer-readable storage medium of claim 11, further comprising program instructions that cause the device to:
determine whether the one or more bit errors are associated with an absorption set of the LDPC code.

13. The computer-readable storage medium of claim 12, wherein execution of the program instructions to generate the corrected codeword causes the device to:
identify the at least one unsatisfied check node based on the absorption set, wherein each of the at least one unsatisfied check node is a neighbor with an odd number of variable nodes in the absorption set.

14. The computer-readable storage medium of claim 11, wherein execution of the program instructions to generate the corrected codeword causes the device to:
determine a plurality of candidate codewords based, at least in part, on the at least one unsatisfied check node, wherein each of the plurality of candidate codewords represents a valid codeword associated with the LDPC code; and
select the corrected codeword from the plurality of candidate codewords.

15. The computer-readable storage medium of claim 14, wherein execution of the program instructions to determine the plurality of candidate codewords causes the device to:
identify one or more absorption sets in the LDPC code that are associated with the at least one unsatisfied check node; and
for each of the one or more absorption sets, determine a set of codewords that satisfies a plurality of parity check constraints associated with the absorption set.

16. The computer-readable storage medium of claim 14, wherein execution of the program instructions to determine the plurality of candidate codewords causes the device to:
look up the plurality of candidate codewords in a lookup table.

17. The computer-readable storage medium of claim 14, wherein execution of the program instructions to select the corrected codeword from the plurality of candidate codewords causes the device to:
select the corrected codeword based, at least in part, on a Euclidean distance between the received codeword and the corrected codeword.

18. The computer-readable storage medium of claim 17, wherein the corrected codeword corresponds to a candidate codeword of the plurality of candidate codewords having a shortest Euclidean distance to the received codeword.

19. The computer-readable storage medium of claim 11, wherein the one or more bit errors in the received codeword corresponds to a decoding error in the LDPC decoding operation.

20. The computer-readable storage medium of claim 11, wherein the device forms a part of a 10GBASE-T Ethernet system.

21. A communications device, comprising:
a receiver to receive a codeword;
a low density parity check (LDPC) decoder to:
perform an LDPC decoding operation on the received codeword using an LDPC code, wherein the decoding operation comprises a plurality of check nodes to attempt to be satisfied by the codeword; and
detect one or more bit errors in the received codeword; and
a processor to generate a corrected codeword based, at least in part, on at least one unsatisfied check node of the plurality of check nodes.

22. The device of claim 21, wherein the processor is to further:
determine whether the one or more bit errors in the received codeword are associated with an absorption set of the LDPC code.

23. The device of claim 22, wherein the processor is to further:
identify the at least one unsatisfied check node based on the absorption set, wherein each of the at least one unsatisfied check node is a neighbor with an odd number of variable nodes in the absorption set.

24. The device of claim 21, wherein the processor is to generate the corrected codeword by:
determining a plurality of candidate codewords based, at least in part, on the at least one unsatisfied check node, wherein each of the plurality of candidate codewords represents a valid codeword associated with the LDPC code; and
selecting the corrected codeword from the plurality of candidate codewords.

25. The device of claim 24, wherein the processor is to determine the plurality of candidate codewords by:
identifying one or more absorption sets in the LDPC code that are associated with the at least one unsatisfied check node; and
for each of the one or more absorption sets, determining a set of codewords that satisfies a plurality of parity check constraints associated with the absorption set.

26. The device of claim 24, wherein the processor is to determine the plurality of candidate codewords by:
looking up the plurality of candidate codewords in a lookup table.

27. The device of claim 24, wherein the processor is to select the corrected codeword from the plurality of candidate codewords by:
selecting the corrected codeword based, at least in part, on a Euclidean distance between the received codeword and the corrected codeword.

28. The device of claim 27, wherein the corrected codeword corresponds to a candidate codeword of the plurality of candidate codewords having a shortest Euclidean distance to the received codeword.

29. The device of claim 21, wherein the one or more bit errors in the received codeword corresponds to a decoding error in the LDPC decoding operation.

30. The device of claim 21, wherein the device forms a part of a 10GBASE-T Ethernet system.

31. A communications device, comprising:
means for receiving a codeword;
means for performing a low density parity check (LDPC) decoding operation on the received codeword using an LDPC code, wherein the decoding operation comprises a plurality of check nodes to attempt to be satisfied by the codeword;
means for detecting one or more bit errors in the received codeword; and
means for generating a corrected codeword based, at least in part, on at least one unsatisfied check node of the plurality of check nodes.

32. The device of claim 31, further comprising:
means for determining that the one or more bit errors are associated with an absorption set of the LDPC code.

33. The device of claim 32, wherein the means for generating the corrected codeword comprises:
means for identifying the at least one unsatisfied check node based on the absorption set, wherein each of the at least one unsatisfied check node is a neighbor with an odd number of variable nodes in the absorption set.

34. The device of claim 31, wherein the means for generating the corrected codeword comprises:
means for determining a plurality of candidate codewords based, at least in part, on the at least one unsatisfied check node, wherein each of the plurality of candidate codewords represents a valid codeword associated with the LDPC code; and
means for selecting the corrected codeword from the plurality of candidate codewords.

35. The device of claim 34, wherein the means for determining the plurality of candidate codewords comprises:
means for identifying one or more absorption sets in the LDPC code that are associated with the at least one unsatisfied check node; and
means for determining a set of codewords for each of the one or more absorption sets that satisfies a plurality of parity check constraints associated with the absorption set.

36. The device of claim 34, wherein the means for determining the plurality of candidate codewords comprises:
means for looking up the plurality of candidate codewords in a lookup table.

37. The device of claim 34, wherein the means for selecting the corrected codeword form the plurality of candidate codewords comprises:
means for selecting the corrected codeword based, at least in part, on a Euclidean distance between the received codeword and the corrected codeword.

38. The device of claim 37, wherein the corrected codeword corresponds to a candidate codeword of the plurality of candidate codewords having a shortest Euclidean distance to the received codeword.

39. The device of claim 31, wherein the one or more bit errors in the received codeword corresponds to a decoding error in the LDPC decoding operation.

40. The device of claim 31, wherein the device forms a part of a 10GBASE-T Ethernet system.
